(19) United States
(12) Patent Application Publication
(10) Pub. No.: US 2011/0315205 A1
(43) Pub. Date: Dec. 29, 2011

(54) LIGHT CONCENTRATOR CUP MODULE

(75) Inventors: FU-YUAN WU, Hsinchu County (TW); WEN-HSIUNG TSOU, Hsinchu County (TW)

(73) Assignee: ADVANCED GREEN ENERGY TECH. CORP., HSINCHU COUNTY (TW)

(21) Appl. No.: 12/824,543

(22) Filed: Jun. 28, 2010

(51) Int. Cl. H01L 31/02

(52) U.S. Cl. 136/256

(57) ABSTRACT

A light concentrator cup module, disposed on a carrying base, said carrying base is provided with a circuit board having a solar energy chip, said light concentrator cup module comprising: a dust-prevention-hood lower cover, disposed on said carrying base and is provided with a first open slot for exposing said circuit board; a dust-prevention-hood upper cover, placed on said dust-prevention-hood lower cover, and is provided with a second open slot corresponding to said solar energy chip; and a light concentrator cup, inserted into said second open slot and corresponds to said solar energy chip. Said light concentrator cup module is capable of guiding sunlight uniformly onto said solar energy chip, thus raising photoelectric conversion efficiency of sunlight.

### BACKGROUND OF THE INVENTION

1. Field of the Invention

The present invention relates to a solar energy device, and in particular to a light concentrator cup module capable of guiding sunlight onto a solar energy chip.

2. The Prior Arts

With the rapid depletion of petroleum energy source, various alternative energy resources have been developed and utilized such as solar energy, wind power energy, hydraulic power energy, and geothermal energy. Since solar energy has the advantages of being stable in supply, pollution free, and non-exhaustible, it has been chosen as a major alternative energy resource under intensive research and development by various countries.

In general, the photoelectric conversion efficiency of a solar energy device is related to its light gathering structure, such that in case it is desired to raise the photoelectric conversion efficiency of a solar energy device, then it is essential that sunlight must be utilized effectively and efficiently. In the prior art, in converting solar energy into electrical energy by a solar energy chip, a concentrator lens is used to gather and focus sunlight onto the solar energy chip, and in such a process, the lens will produce a light concentration area of high light intensity and a light non-concentration area of low light intensity, such that, usually, the solar energy chip is placed in the light concentration area to produce more electricity. However, in such a structure and arrangement, the sunlight gathered at the light non-concentration area can not be utilized effectively, thus leading to the low photoelectric conversion efficiency. In order to redress the problem, a light guidance device is placed in the light non-concentration area, such that the sunlight gathered at the light non-concentration area can be used to enhance that of the light concentration area. As shown in FIG. 1, a spring-plate-shaped light guidance device 16 is locked and fixed onto a supporting base 12 carrying the solar energy circuit board 10 by means of screws 14. However, this kind of light guidance device 16 is formed by bending through utilizing stress, and that will have the problem of stress deformation later on, thus leading to the deviation of light transmission route for the light non-concentration area 18.

Therefore, presently, the design and application of a solar energy device of the prior art are not quite satisfactory, and it has much room for improvement.

### SUMMARY OF THE INVENTION

In view of the problems and shortcomings of the prior art, the present invention provides light concentrator cup module, that can be used to solve the problem of the prior art.

A major objective of the present invention is to provide a light concentrator cup module, which is capable of guiding sunlight uniformly onto a solar energy chip, so as to raise the photoelectric conversion efficiency for the sunlight.

Another objective of the present invention is to provide light concentrator cup module, wherein, the light concentrator cup is formed by inserting a plurality of piece-shaped bodies into one another or it is in a form of a cone-shaped solid body, hereby effectively avoiding the problem of deviation of light transmission route as caused by stress deformation.

A further objective of the present invention is to provide a light concentrator cup module. Wherein, a box formed by a dust-prevention-hood upper cover and a dust-prevention-hood lower cover is utilized to enclose and protect a circuit board, so as to avoid the damages to the electronic elements on the circuit board as caused by the irradiating sunlight.

In order to achieve the above-mentioned objective, the present invention provide a light concentrator cup module disposed on a carrying base, and the carrying base is further provided thereon with a circuit board having a solar energy chip. In the present invention, the a light concentrator cup module comprises: a dust-prevention-hood lower cover provided on the carrying base, and the dust-prevention-hood lower cover is provided with a first open slot exposing the circuit board; a dust-prevention-hood upper cover placed on the dust-prevention-hood lower cover, and it is provided with a second open slot corresponding to the solar energy chip; and a light concentrator cup, including a top end opening and a smaller bottom end opening, which is inserted into the second open slot and corresponding to the solar energy chip.

The present invention provide another light concentrator cup module comprising: a dust-prevention-hood lower cover disposed on a carrying base, the dust-prevention-hood lower cover is provided with a first open slot exposing the circuit board; a dust-prevention-hood upper cover, placed on the dust-prevention-hood lower cover, and is provided with a second open slot corresponding to the solar energy chip; and a light concentrator cup, which is solid cone body with its bottom end smaller than the top end, the light concentrator cup is inserted into the second open slot and corresponds to the solar energy chip.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a cross section view of a light guidance device according to the prior art;

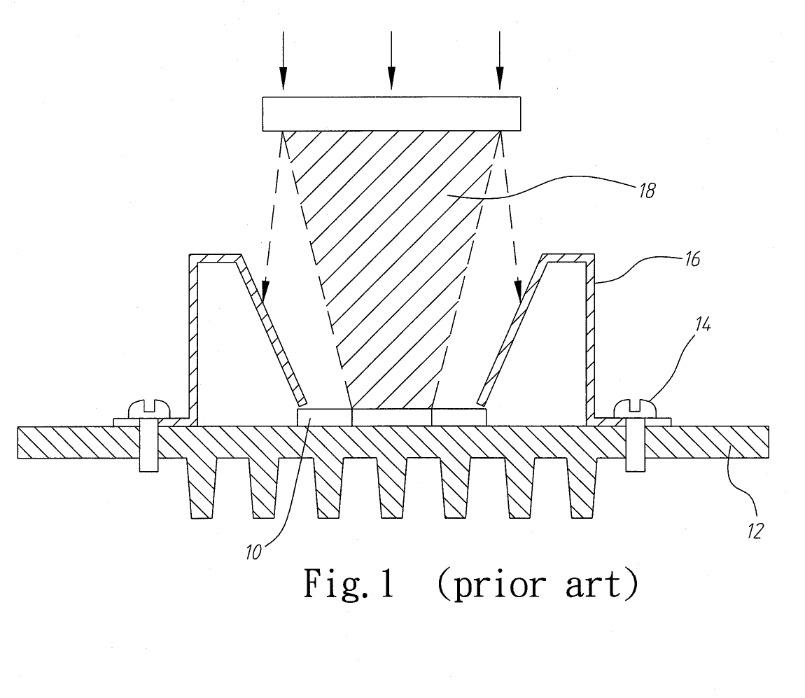

FIG. 2 is a perspective view of a light concentrator cup module according to an embodiment of the present invention;

FIG. 3 is an exploded view of a light concentrator cup module according to an embodiment of the present invention;

FIG. 4 is a perspective view of a light concentrator cup module according to an embodiment of the present invention after the dust-prevention-hood upper cover is removed;

FIG. 5 is an exploded view of elements of a light concentrator cup according to an embodiment of the present invention;

FIG. 6 is a schematic diagram of a light concentrator cup module in a sunlight gathering operation according to an embodiment of the present invention; and

FIG. 7 is a schematic diagram of a light concentrator cup module according to another embodiment of the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings. And, in the following, various embodiments are described in explaining the technical characteristics of the present invention.

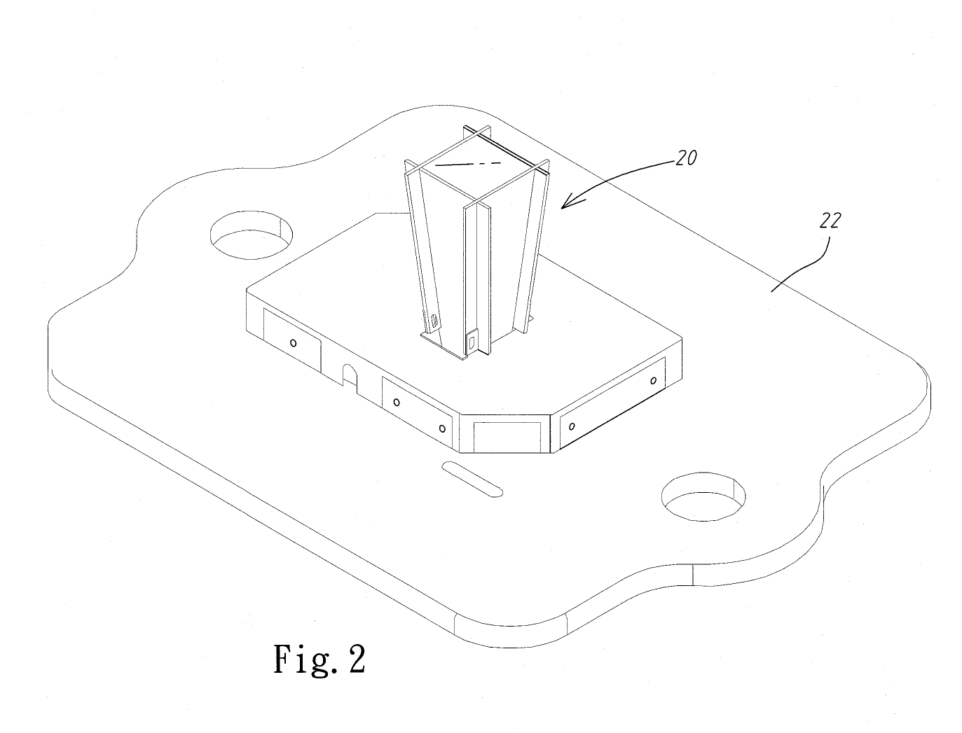

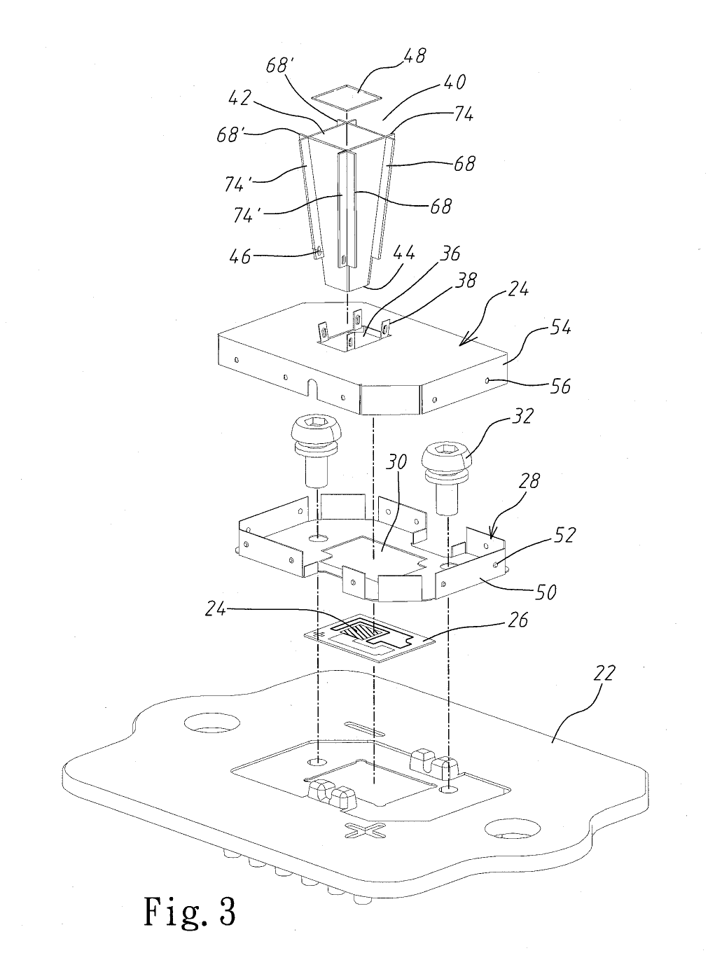

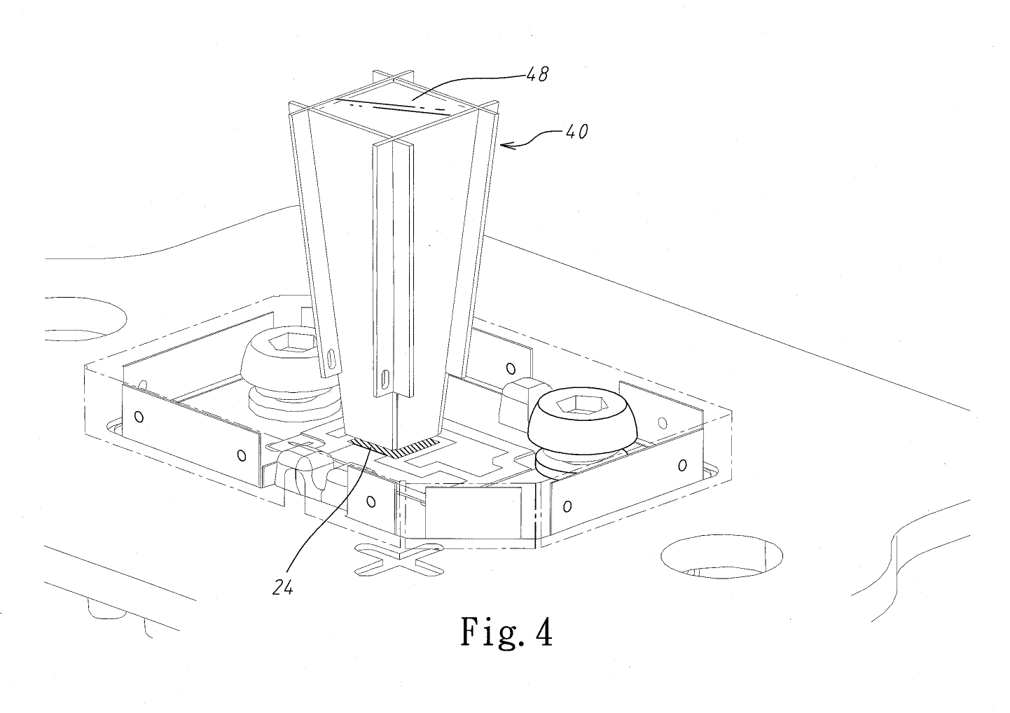

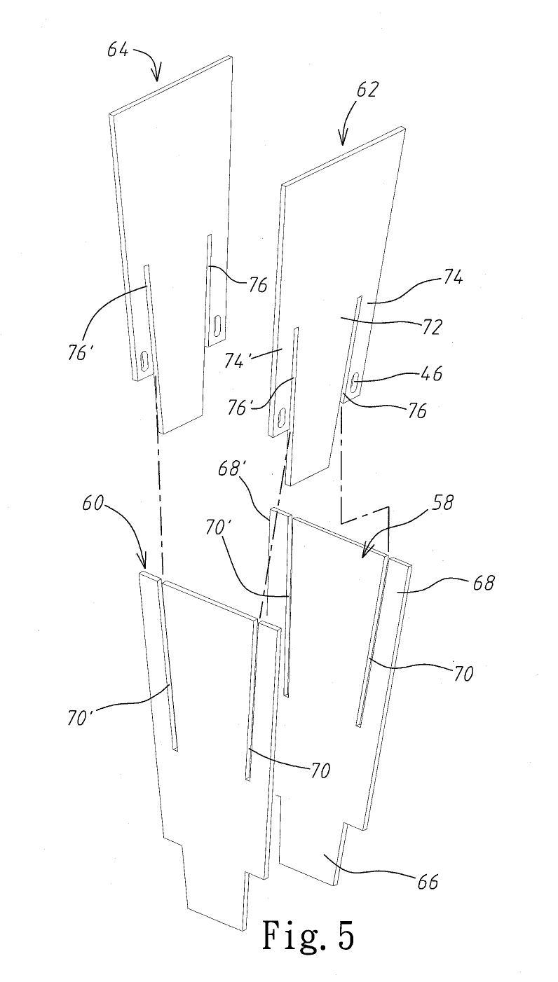

Firstly, refer to the following drawings simultaneously: FIG. 2 for a perspective view of a light concentrator cup module according to an embodiment of the present invention; FIG. 3 for an exploded view of a light concentrator cup module according to an embodiment of the present invention; FIG. 4 for a perspective view of a light concentrator cup module according to an embodiment of the present invention after the dust-prevention-hood upper cover is removed; and FIG. 5 for an exploded view of elements of a light concentrator cup according to an embodiment of the present invention.

As shown in the drawings mentioned above, the light concentrator cup module 20 is disposed on a carrying base 22, that is provided thereon with at least a circuit board 26 having a solar energy chip 24. The carrying base 22 can be a heat dissipation plate, so as to dissipate the heat generated during the operations of a solar energy chip 24, hereby avoiding accumulating too much heat in causing damages to the solar energy chip 24.

The light concentrator cup module 20 of the present invention includes; a dust-prevention-hood lower cover 28 disposed on a carrying base 22, and is provided with a first open slot 30 exposing the circuit board 26, such that the dust-prevention-hood lower cover 28 can be locked and fixed on the carrying base by means of screws 32; a dust-prevention-hood upper cover 34 disposed on the dust-prevention-hood lower cover 28, and is provided with a second open slot 36 corresponding to the solar energy chip 24, and a plurality of fasten-and-fix columns 38 around the perimeter the second open slot 36; and a light concentrator cup 40, that includes a top end opening 42, a bottom end opening 44 smaller than the top end opening 42, and a plurality of fastening slots 46 provided on the outer perimeter of the light concentrator cup 40, that are used to embed the fasten-and-fix columns 38. The bottom end opening 44 of light concentrator cup 40 is inserted into the second open slot 36, thus it corresponds to solar energy chip 24, hereby guiding and focusing sunlight onto the solar energy chip 24, meanwhile avoiding mal-focusing the sunlight onto circuit board 26 in causing damages to the elements thereon. A lens 48 is provided on the top end opening 42 of the light concentrator cup, and it can be a Fresnel lens.

On the side wall 50 of the dust-prevention-hood lower cover 28 is provided with a plurality of positioning protrusion blocks 52, and on the side wall 54 of the dust-prevention-hood upper cover 34 is provided with a plurality of positioning slots 56 corresponding to the positioning protrusion blocks 52, such that when the dust-prevention-hood upper cover 34 is placed onto the dust-prevention-hood lower cover 28, they can be positioned and fixed to each other through the positioning protrusion blocks 52 and the positioning slots 56, hereby forming a box enclosing and protecting the circuit board 26, so as to prevent damages to electronic elements on the circuit board as caused by the irradiating sunlight.

Moreover, the light concentrator cup 40 mentioned above is of a cone-shaped tetragon, as shown in FIG. 5, and is formed by inserting a first piece-shaped body 58, a second piece-shaped body 60, a third piece-shaped body 62, and a fourth piece-shaped body 64 to each other. Therefore, the problem of deviation of light transmission route of the light non-concentration area caused by stress deformation can be avoided. Wherein, the first and second piece-shaped bodies 58 and 60 are the same, also, the third and fourth piece-shaped bodies 62 and 64 are the same.

The first and second piece-shaped bodies 58 and 60 are composed respectively of the following: a first fan-shaped body 66, two first fastening arms 68 and 68′ connected to the opposite sides of the first fan-shaped body 66; and two upward fastening slots 70 and 70′ separating respectively first fastening arms 68 and 68′ and the first fan-shaped body 66; meanwhile, the third and fourth piece-shaped bodies 62 and 64 are composed respectively of the following: a second fan-shaped body 72; two second fastening arms 74 and 74′ connected to the opposite sides of the second fan-shaped body 72, with its bottom end provided with fastening slots 46; and two downward fastening slots 76 and 76′ separating respectively the second fastening arms 74 and 74′ and the second fan-shaped body 72.

When utilizing the first, second, third, and fourth piece-shaped bodies 58, 60, 62, and 64 in assembling them into a light concentrator cup, performing the following operations in sequence: inserting the downward fastening slots 76 of the third piece-shaped body 62 into the upward fastening slots 70 of the first piece-shaped bodies 58; inserting downward fastening slots 76′ of the third piece-shaped body 62 into the upward fastening slots 70 of the second piece-shaped body 60; inserting the downward fastening slots 76 of the fourth piece-shaped body 64 into the upward fastening slots 70′ of the first piece-shaped body 58; and inserting the downward fastening slots 76′ of the fourth piece-shaped body 64 into the upward fastening slots 70′ of the second piece-shaped body 60. Upon finishing the assembly mentioned above, thus forming a cone-shaped light concentrator cup 40 having the first fastening arms 68 and 68′ and the second fastening arms 74 and 74′ disposed protrusively around its perimeter. Therefore, in the structure mentioned above, when inserting the bottom end opening 44 of the light concentrator cup 40 into the second open slot 36, the fastening slots 46 of second fastening arms 74 and 74′ will be inserted and fixed into the fasten-and-fix columns 38 around the perimeter of the second open slot 36, hereby fixing the light concentrator cup 40 into the second open slot 36.

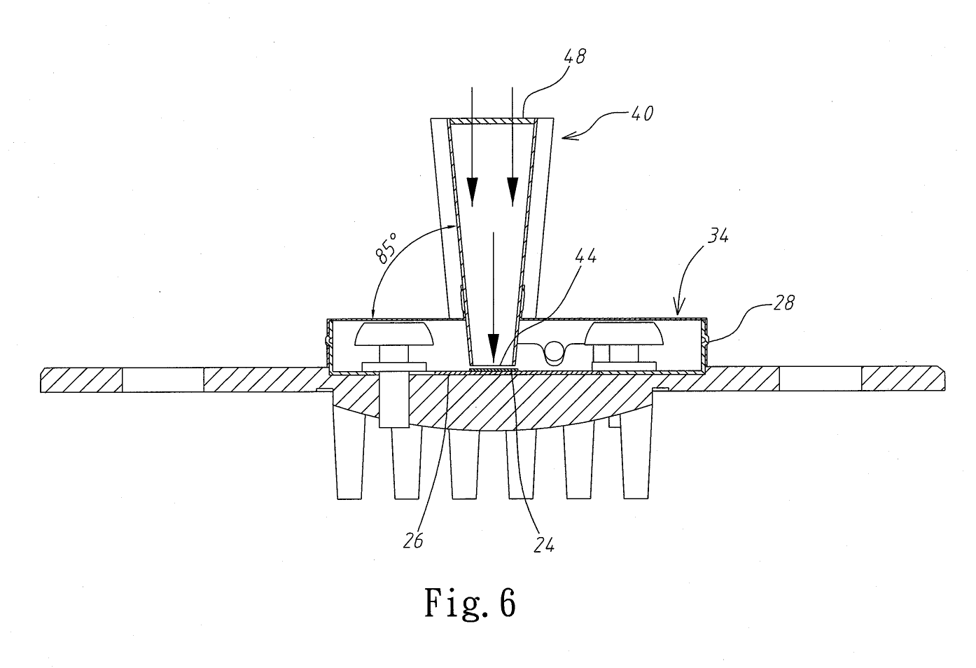

Subsequently, refer to FIG. 6 for a schematic diagram of a light concentrator cup module in a sunlight gathering operation according to an embodiment of the present invention. As shown in FIG. 6, the solar energy chip 24 located near the bottom end opening 44 of the light concentrator cup 40 can not only receive sunlight coming from light concentrator area of the lens 48, but it can also receive sunlight coming from light non-concentrator area of the lens 48 through the light concentrator cup 40, thus raising the photoelectric conversion efficiency of the sunlight. In addition, the angle between the side of the light concentrator cup 40 and the horizontal plane can be 85°±0.5°, so as to achieve optimal light guidance effect.

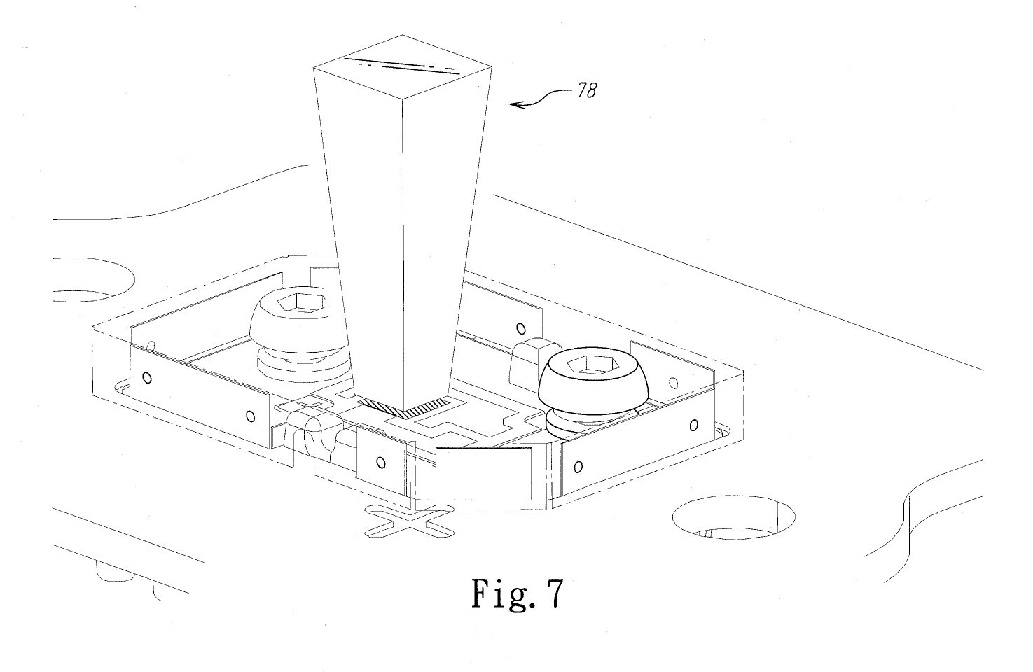

Finally, refer to FIG. 7 for a schematic diagram of a light concentrator cup module according to another embodiment of the present invention. In this embodiment, the light concentrator cup 78 is a solid cone body with its bottom end smaller than the top end, and it is made of quartz or diamond of high light transmittance material.

Summing up the above, the present invention provides a light concentrator cup module, such that sunlight at the light non-concentration area of lens such as Fresnel lens can be guided onto the solar energy chip, so as to raise the photoelectric conversion efficiency of the sunlight. Furthermore, the light concentrator cup of the present invention is made of a plurality piece-shaped bodies inserting into each other or it is in a form of a solid cone body, therefore, the problem of deviation of light transmission route for the light non-concentration area caused by stress deformation can be avoided. In addition, in the present invention, a box formed by a dust-prevention-hood upper cover and a dust-prevention-hood lower cover is used to enclose and protect a circuit board, so as to avoid the damages to the electronic elements on the circuit board as caused by the irradiating sunlight.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A light concentrator cup module, disposed on a carrying base, said carrying base is provided with at least a circuit board having a solar energy chip, comprising:
a dust-prevention-hood lower cover, disposed on said carrying base and is provided with a first open slot for exposing said circuit board;
a dust-prevention-hood upper cover, placed on said dust-prevention-hood lower cover, and is provided with a second open slot corresponding to said solar energy chip; and
a light concentrator cup, including a top end opening and a smaller bottom end opening, that is inserted into said second open slot and corresponds to said solar energy chip.

2. The light concentrator cup module as claimed in claim 1, wherein said carrying base is a heat dissipation plate.

3. The light concentrator cup module as claimed in claim 1, wherein said light concentrator cup is composed of four piece-shaped bodies inserted to each other.

4. The light concentrator cup module as claimed in claim 3, wherein said four piece-shaped bodies include:
a first and a second piece-shaped bodies, each containing a first fan-shaped body, two first fastening arms connected to opposite sides of said first fan-shaped body; and two upward fastening slots separating respectively said first fastening arms and said first fan-shaped body; and
a third and fourth piece-shaped bodies, each containing a second fan-shaped body; two second fastening arms connected to said opposite sides of said second fan-shaped body; and two downward fastening slots separating respectively said second fastening arms and said second fan-shaped body, thus through mutual insertion of said upward fastening slots and downward fastening slots, said first, second, third, and fourth piece-shaped bodies are inserted to each other to form said light concentrator cup.

5. The light concentrator cup module as claimed in claim 4, wherein a fastening slot is provided at bottom end of said fastening arm, and a plurality of fasten-and-fix columns corresponding to said fastening slots are provided around perimeter of said second open slot.

6. The light concentrator cup module as claimed in claim 1, wherein a plurality of positioning protrusion blocks are provided on side wall of said dust-prevention-hood lower cover, and a plurality of positioning slots corresponding to said positioning protrusion blocks are provided on said side wall of said dust-prevention-hood upper cover.

7. The light concentrator cup module as claimed in claim 1, wherein said dust-prevention-hood lower cover is locked and fixed onto said carrying base by means of at least a screw.

8. The light concentrator cup module as claimed in claim 1, further comprising:
a lens, disposed at said top end opening of said light concentrator cup, and is used to receive outside sunlight and transmit it to said solar energy chip through said light concentrator cup.

9. The light concentrator cup module as claimed in claim 3, wherein an angle between a side of said light concentrator cup and a horizontal plane is 85°±0.5°, so as to achieve optimal light guidance effect.

10. A light concentrator cup module, disposed on a carrying base, said carrying base is provided with at least a circuit board having a solar energy chip, comprising:
a dust-prevention-hood lower cover, disposed on said carrying base and is provided with a first open slot for exposing said circuit board;
a dust-prevention-hood upper cover, placed on said dust-prevention-hood lower cover, and is provided with a second open slot corresponding to said solar energy chip; and
a light concentrator cup, is in a form of a solid cone body having a bottom end smaller than a top end, and is inserted into said second open slot and corresponds to said solar energy chip.

11. The light concentrator cup module as claimed in claim 10, wherein said light concentrator cup is made of quartz or diamond.

12. The light concentrator cup module as claimed in claim 10, wherein said carrying base is a heat dissipation plate.

13. The light concentrator cup module as claimed in claim 10, wherein said dust-prevention-hood lower cover is locked and fixed onto said carrying base by means of at least a screw.

14. The light concentrator cup module as claimed in claim 10, wherein an angle between a side of said light concentrator cup and a horizontal plane is 85°±0.5°, so as to achieve optimal light guidance effect.
